(19) United States
(12) Patent Application Publication
(10) Pub. No.: US 2024/0297221 A1
(43) Pub. Date: Sep. 5, 2024

(54) TRANSISTOR STRUCTURE INCLUDING AS-GROWN GRAPHENE AND SEMICONDUCTOR DEVICE INCLUDING THE TRANSISTOR STRUCTURE

(71) Applicants: Samsung Electronics Co., Ltd., Suwon-si (KR); University-Industry Cooperation Group Of Kyung Hee University, Yongin-si (KR)

(72) Inventors: Changseok LEE, Suwon-si (KR); Seunghyun LEE, Hanam-si (KR); Minsu SEOL, Suwon-si (KR); Dohee KIM, Suwon-si (KR); Junseong BAE, Suwon-si (KR); Hyeyoon RYU, Seongnam-si (KR); Sangwon KIM, Suwon-si (KR); Kyung-Eun BYUN, Suwon-si (KR)

(73) Assignees: Samsung Electronics Co., Ltd., Suwon-si, Gyeonggi-do (KR); University-Industry Cooperation Group Of Kyung Hee University, Yongin-si, Gyeonggi-do (KR)

(21) Appl. No.: 18/405,389

(22) Filed: Jan. 5, 2024

(30) Foreign Application Priority Data
Mar. 3, 2023 (KR) 10-2023-0028766

(51) Int. Cl. H01L 29/16; H01L 29/167; H01L 29/417; H01L 29/778

(52) U.S. Cl. CPC H01L 29/1606; H01L 29/167; H01L 29/41725; H01L 29/778

(57) ABSTRACT

A transistor structure may include a semiconductor structure may include a substrate; a source electrode and a drain electrode spaced apart from each other on the substrate; a channel layer connected to the source electrode and the drain electrode; a gate insulating layer on the channel layer; and a gate electrode on the gate insulating layer. The channel layer may include a two-dimensional semiconductor material. The source electrode and the drain electrode each may include a graphene layer and a metal layer. The graphene layer may be formed by as-growing on the substrate. The graphene layer and the metal layer may be side by side in a vertical direction with respect to a surface of the substrate.

### CROSS-REFERENCE TO RELATED APPLICATION

This application is based on and claims priority under 35 U.S.C. § 119 to Korean Patent Application No. 10-2023-0028766, filed on Mar. 3, 2023, in the Korean Intellectual Property Office, the disclosure of which is incorporated by reference herein in its entirety.

### BACKGROUND

### 1. Field

The disclosure relates to a transistor structure including as-grown graphene and a semiconductor device including the transistor structure.

### 2. Description of the Related Art

Transistors are semiconductor devices that serve as electrical switches and are used in various semiconductor products such as memories and driving integrated circuits (IC). As the sizes of semiconductor devices decrease, the number of semiconductor devices that may be integrated into one wafer increases and the driving speeds of semiconductor devices also increase, and thus, research to reduce the sizes of semiconductor devices has been actively conducted.

Recently, research on using two-dimensional materials as a way to reduce the sizes of semiconductor devices has been conducted. Since a two-dimensional material is stable and has excellent properties even at a thin thickness of 1 nm or less, a material that may overcome the limitations of performance degradation due to the reduction of the sizes of semiconductor devices has been in the spotlight.

In the case of graphene, which is attracting attention as a thin film material for semiconductor devices, application difficulties are great due to poor joint performance, and research has been conducted to overcome this.

### SUMMARY

Provided are a transistor structure including as-grown graphene and a semiconductor device including the transistor structure.

Additional aspects will be set forth in part in the description which follows and, in part, will be apparent from the description, or may be learned by practice of the presented embodiments of the disclosure.

According to an example embodiment, a transistor structure may include a substrate; a source electrode and a drain electrode spaced apart from each other on the substrate; a channel layer connected to the source electrode and the drain electrode; a gate insulating layer on the channel layer; and a gate electrode on the gate insulating layer. The channel layer may include a two-dimensional semiconductor material. The source electrode and the drain electrode each may include a graphene layer and a metal layer. The graphene layer may be formed by as-growing on the substrate. The graphene layer and the metal layer may be side by side in a vertical direction with respect to a surface of the substrate.

In some embodiments, in at least one of the source electrode and the drain electrode, the graphene layer and the metal layer may be sequentially stacked on the substrate and the graphene layer may be between the substrate and the channel layer.

In some embodiments, a thickness of the source electrode and a thickness of the drain electrode may be less than about 5 nm.

In some embodiments, at least one of the source electrode and the drain electrode may include a nitride layer on one surface of the graphene layer between the one surface of the graphene layer and the surface of the substrate.

In some embodiments, the nitride layer may include boron nitride (h-BN).

In some embodiments, the gate electrode may include the graphene layer and the metal layer. In the gate electrode, the graphene layer and the metal layer may be arranged in parallel in the vertical direction with respect to the surface of the substrate.

In some embodiments, in the source electrode and the drain electrode, an inside of the graphene layer may be doped with at least one of N, S, B, P, O, and F.

In some embodiments, the surface of the graphene layer may be doped with a dopant, and the dopant may include at least one of Pd, Ti, W, Al, Ni, Cu, Ru, Ag, Au, and Pt.

In some embodiments, the metal layer may include at least one of Rd and Pd.

In some embodiments, the channel layer may include a transition metal dichalcogenide (TMD).

In some embodiments, the TMD may include a metal element and a chalcogen element. The metal element may include at least one of Mo, W, Nb, V, Ta, Ti, Zr, Hf, Tc, Re, Cu, Ga, In, Sn, Ge, and Pb. The chalcogen element may include at least one of S, Se, and Te.

In some embodiments, the gate electrode may include at least one of tungsten (W), molybdenum (Mo), ruthenium (Ru), polysilicon, TiN, a metallic two-dimensional material, or a combination thereof.

In some embodiments, the metallic two-dimensional material may include at least one of graphene, TaS₂, TaSe₂, NbS₂, NbSe₂, PdTe₂, PtTe₂, NbTe₂, TiSe₂, VSe₂, AuSe, and MoTe₂.

According to another an example embodiment, a semiconductor device may include a transistor structure; and a plurality of capacitors in the transistor structure. The transistor structure may include a substrate, a source electrode and a drain electrode spaced apart from each other on the substrate, a channel layer connected to the source electrode and the drain electrode, a gate insulating layer on the channel layer, and a gate electrode on the gate insulating layer. The channel layer may include a two-dimensional semiconductor material. The source electrode and the drain electrode each may include a graphene layer and a metal layer. The graphene layer may be formed by as-growing on the substrate. The graphene layer and the metal layer may be arranged side by side in a vertical direction with respect to a surface of the substrate.

In some embodiments, the graphene layer may be between the substrate and the metal layer.

In some embodiments, a thickness of the source electrode and a thickness of the drain electrode may be less than about 5 nm.

In some embodiments, at least one of the source electrode and the drain electrode may include a nitride layer on one surface of the graphene layer between the one surface of the graphene layer and the surface of the substrate.

In some embodiments, the nitride layer may include boron nitride (h-BN).

In some embodiments, the graphene layer may be doped inside with a dopant, and the dopant may include at least one of N, S, B, P, O, and F.

In some embodiments, the surface of the graphene layer may be doped with a dopant, and the dopant may include at least one of Pd, Ti, W, Al, Ni, Cu, Ru, Ag, Au, and Pt.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a transistor according to an embodiment;

FIG. 2 is a cross-sectional view illustrating a transistor according to another embodiment;

FIG. 3 is a cross-sectional view illustrating a transistor according to another embodiment;

FIGS. 4A to 4C are cross-sectional views illustrating inverters according to some embodiments;

FIGS. 5A and 5B are circuit diagrams according to an embodiment; and

FIGS. 6 and 7 are conceptual diagrams schematically illustrating a device architecture applicable to an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, embodiments will be described in detail with reference to the accompanying drawings. In the following drawings, the same reference numerals refer to the same components, and the size of each component in the drawings may be exaggerated for clarity and convenience of description. Meanwhile, embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with”. Singular expressions include plural expressions unless the context clearly means otherwise. In addition, when a part “contains” a component, this means that it may contain other components, rather than excluding other components, unless otherwise stated.

The use of the term “the” and similar indicative terms may correspond to both singular and plural. Unless there is clear order or contrary description of the steps constituting the method, these steps may be performed in the appropriate order, and are not necessarily limited to the order described.

Further, the terms “unit”, “module” or the like mean a unit that processes at least one function or operation, which may be implemented in hardware or software or implemented in a combination of hardware and software.

The terms first, second, etc. may be used to describe various components, but the components should not be limited by terms. Terms are used only for the purpose of distinguishing one component from another.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

Graphene is a material with a hexagonal honeycomb structure where carbon atoms are two-dimensionally connected, and has a very thin thickness at the level of an atom. The graphene has higher electrical mobility and superior thermal characteristics than silicon (Si), is chemically stable, and has a large surface area. Such graphene may be used as a metal barrier. As-growing of graphene on a non-catalyst substrate may be required to introduce a semiconductor process. In order to increase the applicability of the as-grown graphene as a metal barrier, the resistance of the main metal material deposited on the graphene may need to be lower than the resistance of the main metal material deposited on the existing barrier metal.

In the following embodiments, a transistor structure including an electrode in which graphene and a metal are combined by as-growing graphene on a semiconductor substrate and a semiconductor device including the same will be described.

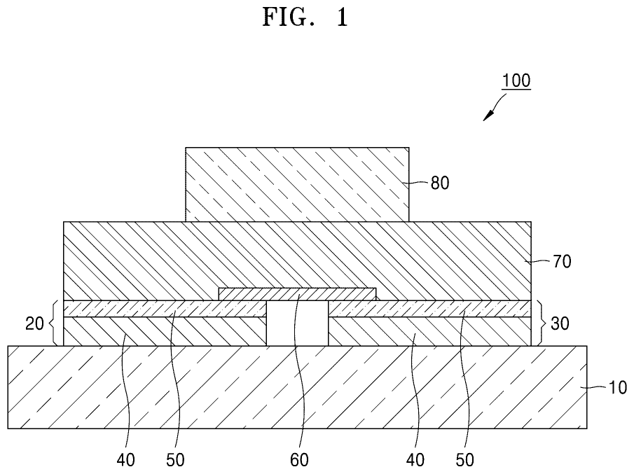

FIG. 1 is a cross-sectional view illustrating a transistor structure 100 according to an embodiment.

The transistor structure 100 shown in FIG. 1 may include, for example, a Field Effect Transistor (FET).

Referring to FIG. 1, a source electrode 20 and a drain electrode 30 are arranged to be spaced apart from each other on a substrate 10. A channel layer 60 is arranged on the source electrode 20 and the drain electrode 30 in which the source electrode 20 and the drain electrode 30 are connected by the channel layer 60, and a gate insulating layer 70 and a gate electrode 80 are arranged on the channel layer 60. Each of the source electrode 20 and the drain electrode 30 includes a graphene layer 40 and a metal layer 50, and each of the graphene layer 40 and the metal layer 50 may be arranged side by side (e.g., stacked) in a vertical direction to the surface of the substrate 10.

The substrate 10 may include a semiconductor material, a metal material, or an insulating material. The substrate 10 may include, for example, a semiconductor material. The semiconductor material may include, for example, a Group IV semiconductor material or semiconductor compound. As a specific example, the substrate 10 may include a Group IV semiconductor material including at least one of Si, Ge, Sn, and C, a Group III-V compound semiconductor material in which at least one material of B, Ga, In, and Al and at least one material of N, P, As, Sb, S, Se, and Te are combined, or a Group II-VI compound semiconductor material in which at least one material of Be, Mg, Cd, and Zn and at least one material of O, S, Se, and Te are combined. The substrate 10 may include a metal material. The metal material may include, for example, at least one of Cu, Mo, Ni, Al, W, Ru, Co, Mn, Ti, Ta, Au, Hf, Zr, Zn, Y, Cr, Gd, Rh, Ir, Os, TiN, and TaN. In addition, the substrate 10 may include an insulating material. The insulating material may include, for example, an oxide, a nitride, or a carbide. As a specific example, the substrate 10 may include an oxide including at least one of Si, Ge, Al, Hf, Zr, and La, or a Si nitride. However, the materials of the substrate 10 mentioned above are only illustrative, and the substrate 10 may include various other materials.

Meanwhile, the substrate 10 may further include a dopant. For example, when the substrate 10 includes a semiconductor material, the substrate may be doped with a dopant. For example, the substrate 10 includes a Group IV semiconductor material, for example, may be mainly doped with B, P, As, or the like. The substrate 10 includes a Group III-V semiconductor material and may be doped with, for example, Si, C, Te, Se, Mo, or the like.

For example, the substrate 10 may include at least one of single crystal silicon, amorphous silicon, polysilicon, and silicon oxide, various semiconductor materials or semiconductor compounds, metal materials, or insulating materials described above.

The source electrode 20 and the drain electrode 30 may be arranged on the substrate 10.

Each of the source electrode 20 and the drain electrode 30 may include a graphene layer 40 and a metal layer 50. The graphene layer 40 may be formed by being as-grown on the substrate 10.

The as-grown graphene is as-grown on the surface of the substrate 10 and may be adjusted to increase the surface energy thereof. The as-grown graphene may be formed to include nanocrystalline graphene with a domain size of 100 nm or less, but is not limited thereto.

In this embodiment, the surface energy control of the as-grown graphene may be performed by any one of dopant gas injection during as-growing of graphene, plasma treatment using plasma gas after as-growing of graphene, and UV-ozone treatment after as-growing of graphene. For example, during as-growing of graphene, a doping gas containing an N component may be injected to form dopant, for example, as-grown graphene doped with an N component. In addition, after as-growing of graphene, for example, the as-grown graphene may be plasma-treated with a gas including an N component. In addition, after as-growing of graphene, the as-grown graphene may be UV-ozone-treated. Besides, the surface energy of the as-grown graphene may be adjusted through post-treatment such as wet chemical treatment such as HF after as-growing of graphene.

The surface energy of the as-grown graphene may be changed by injecting doping gas during as-growing of graphene, and post-treatment after the as-growing of graphene, and a graphene layer 40 with the as-grown graphene with adjusted surface energy in a direction in which the surface energy increases may be formed to improve properties such as adhesion and resistance.

The source electrode 20 and the drain electrode 30 may include the graphene layer 40 including the as-grown graphene and the metal layer 50, or a layer in which the graphene layer 40 and the metal layer 50 are combined.

The graphene layer 40 and the metal layer 50 included in each of the source electrode 20 and the drain electrode 30 may be arranged side by side in a vertical direction to the surface of the substrate 10.

The graphene layer 40 and the metal layer 50 may be arranged between the substrate 10 and the channel layer 60, and may be arranged in order from the substrate 10 in the vertical direction of the surface of the substrate 10. The metal layer 50 may be arranged on the graphene layer 40.

The graphene layer 40 included in each of the source electrode 20 and the drain electrode 30 may be doped with a dopant to reduce contact resistance with the channel layer 60. The graphene layer 40 may be doped on the surface and inside of the graphene layer using a dopant.

The inside of the graphene layer 40 may be doped with a dopant, and the dopant may include at least one of N, S, B, P, O, and F, but the embodiments are not limited thereto.

The surface of the graphene layer 40 may be doped with a dopant including at least one of Pd, Ti, W, Al, Ni, Cu, Ru, Ag, Au, and Pt, but the embodiments are not limited thereto. The doping of the graphene layer 40 described above is to reduce contact resistance between the electrode including the graphene layer 40 and the channel layer.

The metal layer 50 may be formed on one surface of the graphene layer 40, or may be formed by doping the graphene layer 40 with the dopant described above. The metal layer 50 may facilitate to form a complementary metal-oxide semiconductor (CMOS) and may include at least one of Rd and Pd, which are low-reactivity materials, but the embodiments are not limited thereto.

The total thicknesses of the source electrode 20 and the drain electrode 30 may be about 1 nm or more to about 5 nm or less, but the embodiments are not limited thereto. The thicknesses of the source electrode and the drain electrode may form an ultra-thin structure and contribute to miniaturization of the transistor.

The channel layer 60 may include a two-dimensional semiconductor material. The two-dimensional semiconductor material refers to a two-dimensional material with a layered structure where constituent atoms are two-dimensionally bonded. The two-dimensional semiconductor material may have excellent electrical properties and may maintain high mobility without significantly changing its properties even when its thickness is reduced to a nano-scale.

The two-dimensional semiconductor material may include a material having a band gap of approximately 0.5 eV or more and 3.0 eV or less. For example, the two-dimensional semiconductor material may include Transition Metal Dichalcogenide (TMD) or black phosphorus. However, the embodiments are not limited thereto. The TMD is a two-dimensional material having a semiconductor characteristic and is a compound of a transition metal and a chalcogen element. Here, the transition metal may include, for example, at least one of Mo, W, Nb, V, Ta, Ti, Zr, Hf, Co, Tc, and Re, and the chalcogen element may include at least one of, for example, S, Se, and Te. As a specific example, the TMD may include MoS₂, MoSe₂, MoTe₂, WS₂, WSe₂, WTe₂, ZrS₂, ZrSe₂, HfS₂, HfSe₂, NbSe₂, ReSe₂, etc. However, the embodiments are not limited thereto. Black phosphorus is a semiconductor material having a structure in which phosphorus (P) atoms are two-dimensionally bonded.

The channel layer 60 may be arranged between the source electrode 20 and the drain electrode 30, and may be arranged to connect both electrodes with each other. The channel layer 60 may be arranged on the same plane as the source electrode 20 and the drain electrode 30, or may be arranged on an upper portion of each of both electrodes.

The gate electrode 80 may be arranged on the gate insulating layer 70. Although not shown, the gate electrode 80 may include a graphene layer 40 and a metal layer 50, and the graphene layer 40 and the metal layer 50 described above may be arranged side by side in a vertical direction to the surface of the substrate 10.

The gate electrode 80 may include a metallic two-dimensional material instead of the graphene layer 40, for example, TaS₂, NbSe₂, and TiSe₂, but is not limited thereto.

The gate electrode 80 may include at least one conductive material among tungsten (W), molybdenum (Mo), ruthenium (Ru), polysilicon, TiN, and a metallic two-dimensional material, or a combination thereof, and the metallic two-dimensional material may include at least one of graphene, TaS₂, TaSe₂, NbS₂, NbSe₂, PdTe₂, PtTe₂, NbTe₂, TiSe₂, VSe₂, AuSe, and MoTe₂, but is not limited thereto.

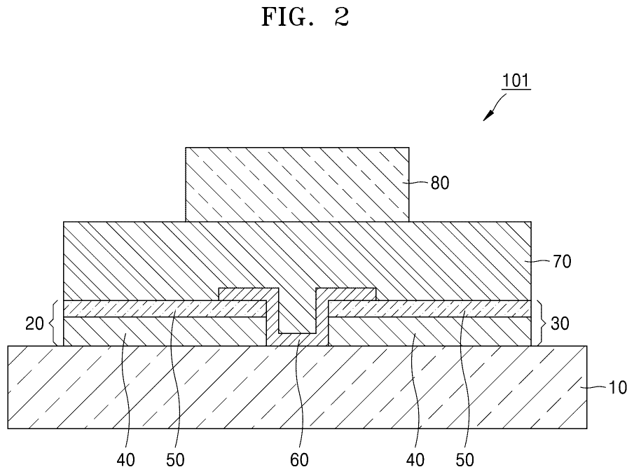

FIG. 2 is a cross-sectional view illustrating a transistor according to another embodiment.

The transistor structure 101 according to an embodiment described in FIG. 2 may include the same configuration as the component described in FIG. 1.

The channel layer 60 of the transistor structure 101 according to an embodiment may connect the source electrode 20 and the drain electrode 30, may extend along either side of the source electrode 20 and the drain electrode 30, and may be arranged to cover a part of the surface of the substrate 10. The channel layer 60 may include a two-dimensional semiconductor material such as TMD, and the following description is as described above.

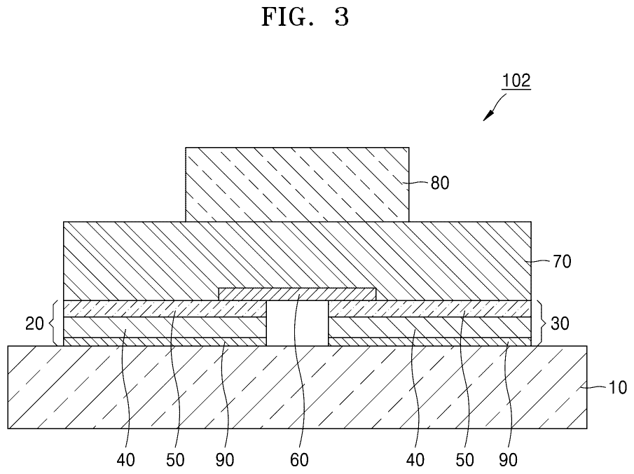

FIG. 3 is a cross-sectional view illustrating a transistor according to another embodiment.

Referring to FIG. 3, a transistor structure 102 further including a nitride layer 90 in the transistor structure described in FIG. 1 is described.

The nitride layer 90 may be arranged on one surface of the graphene layer 40 of the transistor structure 102 according to an embodiment, and formed on the opposite surface of the channel layer 60 thereof. The nitride layer 90 formed on one side surface of the channel layer 60 may reduce a surface scattering effect to be described later.

In the semiconductor device, the mobility of electrons may be changed according to the gate voltage. Charges of an inversion layer may be induced by a vertical electric field, and the moving electrons may be induced to the surface by a positive gate voltage. In other words, when moving from the source electrode to the drain electrode through the channel layer, the moving electrons are attracted to the surface, which is called the surface scattering effect, and may be one of the causes of reducing the mobility of electrons.

The nitride layer 90 may include a material including a nitrogen element, for example, boron nitride (h-BN), but is not necessarily limited thereto.

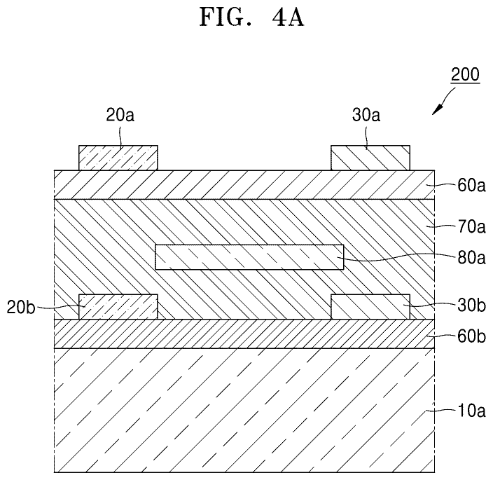

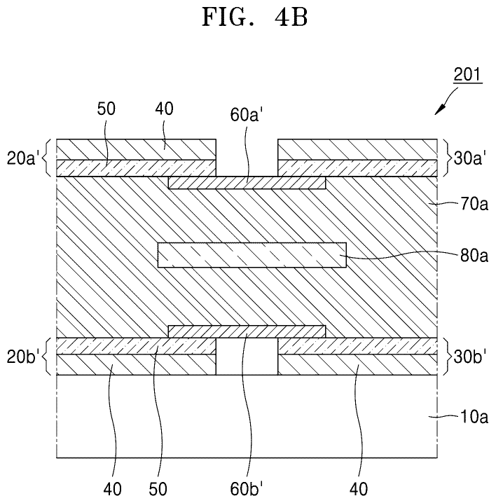

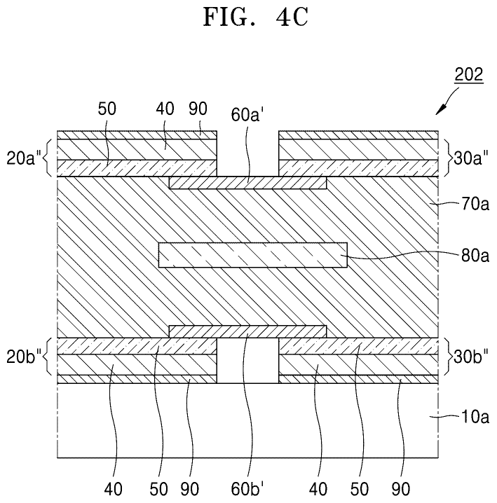

FIGS. 4A to 4C are cross-sectional views illustrating inverters according to some embodiments.

An inverter according to an embodiment may be a CMOS inverter. The CMOS inverter has a structure in which the gates of NMOSFET and PMOSFET are connected to receive an input voltage Vin, and the drains of NMOSFET and PMOSFET are connected to produce an output voltage Vout.

Referring to FIG. 4A, the inverter 200 may include channel layers 60a and 60b arranged on the substrate 10a, source electrodes 20a and 20b and drain electrodes 30a and 30b, which are provided in each channel layer, a common gate insulating layer 70a, and a common gate electrode 80a.

Each of the channel layers 60a and 60b may include different polarities, and for example, when the first channel layer 60a is an n-type channel, the second channel layer 60b may be a p-type channel.

An inverter 200a to which a common gate electrode is applied may form one electronic device including two transistors and two resistors, and the channel layers 60a and 60b may be arranged on the electrode or on the same plane.

Referring to FIG. 4B, an inverter 201 may be similar to the inverter 200 in FIG. 4A, except the channel layers 60a′ and 60b′ may have widths that are less than the width of the common gate insulating layer 70a. The channel layer 60a′ may contact end regions of the source electrode 20a′ and drain electrode 30a′. The channel layer 60b′ may contact end regions of the source electrode 20b′ and drain electrode 30b′. The source electrodes 20a′ and 20b′ and the drain electrodes 30a′ and 30b′ each may include a graphene layer 40 and a metal layer 50. The metal layer 50 may be between the graphene layer 40 and the gate insulating layer 70a and the metal layer 50 may be between the graphene layer 40 and an adjacent one of the channel layers 60a′ and 60b′.

Referring to FIG. 4C, an inverter 202 may be the same as the inverter 201 in FIG. 4B, but the source electrodes 20a″ and 20b″ and the drain electrodes 30a″ and 30b″ each may include a nitride layer 90 on a surface of the graphene layer 40 opposite a surface of the graphene layer 50 contacting the metal layer 50.

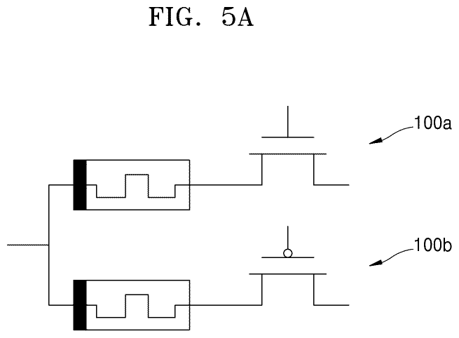

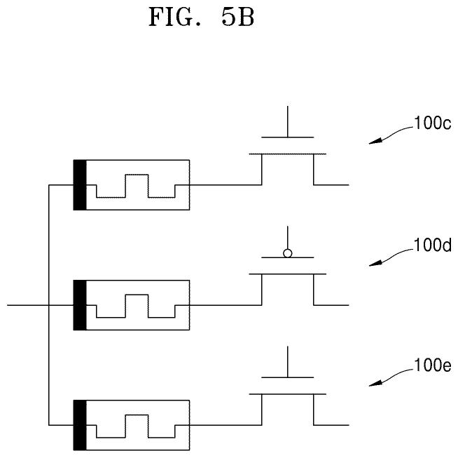

FIGS. 5A and 5B are circuit diagrams according to an embodiment.

Referring to FIGS. 5A and 5B, a circuit schematic diagram including a plurality of transistors (e.g., 100a, 100b, 100c, 100d, 100e) and a plurality of resistors is shown.

An electronic device including a plurality of transistors and a plurality of resistors as well as an electronic device in which one transistor and one resistor are connected may be included. The plurality of transistors and the plurality of resistors may include two transistors and two resistors (2T2R) and three transistors and three resistors (3T3R), but are not limited thereto.

Circuits corresponding to the circuit diagrams in FIGS. 5A and 5B may include one of the transistor structures 100, 101, and 102 described above.

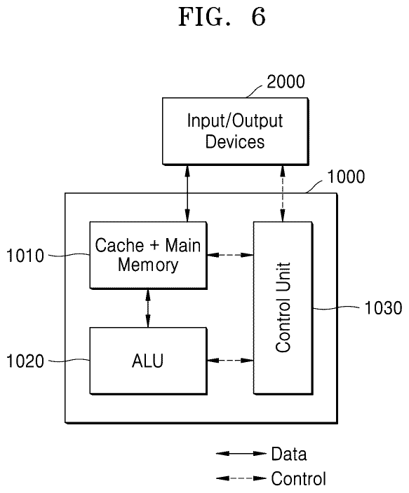

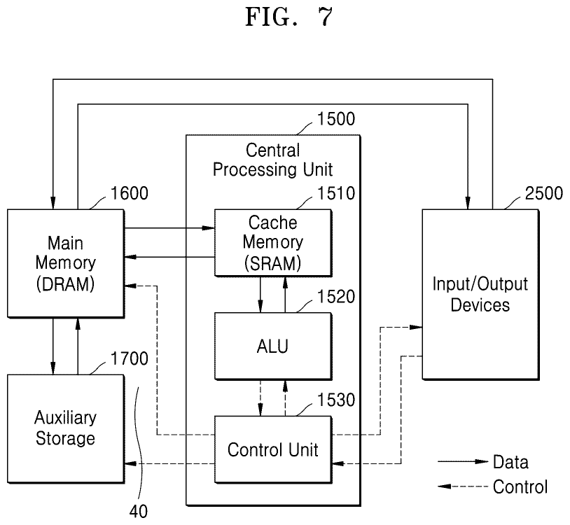

FIGS. 6 and 7 are conceptual diagrams schematically illustrating a device architecture applicable to an electronic device according to embodiments.

Referring to FIG. 6, the device architecture 1000 may include a memory unit 1010, an arithmetical logic unit (ALU) 1020, and a control unit 1030. The memory unit 1010, the ALU 1020, and the control unit 1030 may be electrically connected with one another. For example, an electronic device architecture 1000 may be implemented as a single chip including the memory unit 1010, the ALU 1020, and the control unit 1030. Specifically, the memory unit 1010, the ALU 1020, and the control unit 1030 may be connected to each other by a metal line in an on-chip to directly communicate with each other. The memory unit 1010, the ALU 1020, and the control unit 1030 may be monolithically integrated on one substrate to constitute one chip. An input/output element 2000 may be connected to the device architecture 1000. In addition, the memory unit 1010 may include both a main memory and a cache memory. Here, the main memory may include a DRAM device. The device architecture 1000 may be an on-chip memory processing unit. The device architecture 1000, for example in the memory unit 1010, ALU 1020, and/or control unit 1030, may include one of the transistor structures 100, 101, and 102 or inverters 200, 201, 202 described above.

Referring to FIG. 7, a cache memory 1510, an ALU 1520, and a control unit 1530 may configure a Central Processing Unit (CPU) 1500, and the cache memory 1510 may include a static random access memory (SRAM). A main memory 1600 and an auxiliary storage 1700 may be provided separately from the CPU 1500. The main memory 1600 may include the DRAM device described above. In some cases, the device architecture may be implemented in a form in which computing unit devices and memory unit devices are adjacent to each other on a single chip, regardless of sub-units.

The device architecture in FIG. 7, for example in the memory unit 1010, ALU 1020, and/or control unit 1030, may include one of the transistor structures 100, 101, and 102 or inverters 200, 201, 202 described above.

In some cases, the electronic device architecture may be implemented in a form in which computing unit devices and memory unit devices are adjacent to each other on a single chip, regardless of sub-units. Although embodiments have been described above, this is merely an example, and various modifications may be made therefrom to those skilled in the art.

The transistor structure according to an embodiment may include an electrode in which a graphene layer as-grown on a substrate and a metal layer are combined, thereby reducing contact resistance.

The semiconductor device including a transistor structure according to an embodiment includes an electrode in which a graphene layer as-grown on a substrate and a metal layer are combined, thereby reducing contact resistance between the substrate and the electrode.

The semiconductor device, and the electronic device including the semiconductor device have been described with reference to the embodiments shown in the drawings, but this is only an example, and those of ordinary skill in the art will understand that various modifications and equivalent other embodiments are possible. Therefore, the disclosed embodiments should be considered from an explanatory point of view rather than a limiting point of view. The scope of the right is defined not by the detailed description but by the appended claims, and all differences within the scope will be construed as being included in the scope of the right.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A transistor structure comprising:
a substrate;
a source electrode and a drain electrode spaced apart from each other on the substrate;
a channel layer connected to the source electrode and the drain electrode;
a gate insulating layer on the channel layer; and
a gate electrode on the gate insulating layer, wherein
the channel layer includes a two-dimensional semiconductor material,
the source electrode and the drain electrode each include a graphene layer and a metal layer,
the graphene layer is formed by as-growing on the substrate, and
the graphene layer and the metal layer are side by side in a vertical direction with respect to a surface of the substrate.

2. The transistor structure of claim 1, wherein
in at least one of the source electrode and the drain electrode, the graphene layer and the metal layer are sequentially stacked on the substrate and the graphene layer is between the substrate and the channel layer.

3. The transistor structure of claim 1, wherein
a thickness of the source electrode and a thickness of the drain electrode are less than about 5 nm.

4. The transistor structure of claim 1, wherein
at least one of the source electrode and the drain electrode include a nitride layer on one surface of the graphene layer between the one surface of the graphene layer and the surface of the substrate.

5. The transistor structure of claim 4, wherein the nitride layer comprises boron nitride (h-BN).

6. The transistor structure of claim 1, wherein
the gate electrode comprises the graphene layer and the metal layer, and
in the gate electrode, the graphene layer and the metal layer are arranged in parallel in the vertical direction with respect to the surface of the substrate.

7. The transistor structure of claim 1, wherein
in the source electrode and the drain electrode, an inside of the graphene layer is doped with at least one of N, S, B, P, O, and F.

8. The transistor structure of claim 1, wherein
the surface of the graphene layer is doped with a dopant, and
the dopant includes at least one of Pd, Ti, W, Al, Ni, Cu, Ru, Ag, Au, and Pt.

9. The transistor structure of claim 1, wherein the metal layer comprises at least one of Rd and Pd.

10. The transistor structure of claim 1, wherein the channel layer comprises a transition metal dichalcogenide (TMD).

11. The transistor structure of claim 10, wherein
the TMD comprises a metal element and a chalcogen element,
the metal element includes at least one of Mo, W, Nb, V, Ta, Ti, Zr, Hf, Tc, Re, Cu, Ga, In, Sn, Ge, and Pb, and
the chalcogen element includes at least one of S, Se, and Te.

12. The transistor structure of claim 1, wherein
the gate electrode comprises at least one of tungsten (W), molybdenum (Mo), ruthenium (Ru), polysilicon, TiN, a metallic two-dimensional material, or a combination thereof.

13. The transistor structure of claim 12, wherein
the metallic two-dimensional material comprises at least one of graphene, TaS₂, TaSe₂, NbS₂, NbSe₂, PdTe₂, PtTe₂, NbTe₂, TiSe₂, VSe₂, AuSe, and MoTe₂.

14. A semiconductor device comprising:
a transistor structure; and
a plurality of capacitors in the transistor structure, wherein
the transistor structure includes
a substrate,
a source electrode and a drain electrode spaced apart from each other on the substrate,
a channel layer connected to the source electrode and the drain electrode,
a gate insulating layer on the channel layer, and
a gate electrode on the gate insulating layer, wherein
the channel layer includes a two-dimensional semiconductor material,
the source electrode and the drain electrode each include a graphene layer and a metal layer,
the graphene layer is formed by as-growing on the substrate, and
the graphene layer and the metal layer are arranged side by side in a vertical direction with respect to a surface of the substrate.

15. The semiconductor device of claim 14, wherein the graphene layer is between the substrate and the metal layer.

16. The semiconductor device of claim 14, wherein a thickness of the source electrode and a thickness of the drain electrode are less than about 5 nm.

17. The semiconductor device of claim 14, wherein
at least one of the source electrode and the drain electrode include a nitride layer on one surface of the graphene layer between the one surface of the graphene layer and the surface of the substrate.

18. The semiconductor device of claim 17, wherein the nitride layer comprises boron nitride (h-BN).

19. The semiconductor device of claim 14, wherein
the graphene layer is doped inside with a dopant, and
the dopant includes at least one of N, S, B, P, O, and F.

20. The semiconductor device of claim 14, wherein
the surface of the graphene layer is doped with a dopant, and
the dopant includes at least one of Pd, Ti, W, Al, Ni, Cu, Ru, Ag, Au, and Pt.
